(19) United States
(12) Patent Application Publication
(10) Pub. No.: US 2020/0103221 A1
(43) Pub. Date: Apr. 2, 2020

(54) METHOD FOR DETERMINING THE HEIGHT OF A LAYER OF CARBON NANOTUBES

(71) Applicants: COMMISSARIAT A L'ENERGIE ATOMIQUE ET AUX ENERGIES ALTERNATIVES, Paris (FR); CENTRE NATIONAL DE LA RECHERCHE SCIENTIFIQUE, Paris (FR); UNIVERSITE CLAUDE BERNARD LYON 1, Villeurbanne Cedex (FR)

(72) Inventors: Raphael RAMOS, Grenoble Cedex 09 (FR); Lorie DAVID, Grenoble Cedex 09 (FR); Jean DIJON, Grenoble Cedex 09 (FR)

(73) Assignees: COMMISSARIAT A L'ENERGIE ATOMIQUE ET AUX ENERGIES ALTERNATIVES, Paris (FR); CENTRE NATIONAL DE LA RECHERCHE SCIENTIFIQUE, Paris (FR); UNIVERSITE CLAUDE BERNARD LYON 1, Villeurbanne Cedex (FR)

(21) Appl. No.: 16/583,309

(22) Filed: Sep. 26, 2019

(30) Foreign Application Priority Data
Sep. 28, 2018 (FR) 18 58983

(51) Int. Cl. G01B 11/06; C23C 16/26; C23C 16/458

(52) U.S. Cl. CPC G01B 11/0608; C23C 16/4583; C23C 16/26

(57) ABSTRACT

A method for measuring the height of a forest of carbon nanotubes, containing:
a) providing a substrate having a growth area containing at least one measurement zone containing a growth zone and a sterile zone, the growth zone being defined by a segment of the substrate containing a growth catalyst of the nanotubes, and
b) growing catalytically by CVD the forest of nanotubes in the growth zone,
   wherein, at least in step b) contains:
irradiating the measurement zone with an incident light beam; measuring, at various times, the intensity of the beam reflected by the measurement zone; and determining the height of the forest of nanotubes from the reflected-beam intensities measured at the various times.

The present invention relates to a method for measuring the height of a forest of nanotubes in growth.

The synthesis of forests of carbon nanotubes is carried out industrially by chemical vapour deposition (CVD) on a carrier covered with a catalyst of the growth of the nanotubes. Such a method is particularly sensitive to the many process parameters of a CVD deposition reactor and to environmental conditions (temperature and humidity for example). It is in particular difficult to make it so that a desired height of the forest of nanotubes is reproducibly obtained, as is for example described in the article C. Ryan Oliver et al., “Statistical analysis of variation in laboratory growth of carbon nanotubes forests and recommendations for improved consistency”, ACS NANO, vol. 7, No. 4, pp 3565-3580, 2013.

However, for certain applications, for example when the forest of nanotubes is intended to form an interposed unit for the thermal management of an electronic component, or to form a wire or a sheet, it is necessary to produce a forest with a controlled height.

Methods are known for determining the variation in the height of a forest of nanotubes in growth.

For example, the article A. A. Puretzky et al., “real-time imaging of vertically aligned carbon nanotube array growth kinetics”, Nanotechnology, 19 (2008), p. 05560 describes a method for tracking height by means of images taken using a zoom lens. A succession of images of the cross section of a forest of nanotubes in growth located on the edge of a substrate is analysed. However, apart from its limited resolution, such a method is limited to tracking growth on substrates of a size smaller than industrial substrates. Specifically, it is necessary for the growth on the periphery of the substrate to be substantially uniform with that at the centre of the substrate. Such a method cannot therefore be implemented industrially.

The article E. R. Meshot and A. J. Hart, “Abrupt self-termination of vertically aligned carbon nanotube growth”, Applied Physics Letters 92, 113107 (2208), proposes to detect the position of a segment of the upper face of a forest of nanotubes in growth by means of a laser beam. However, because of the optically absorbing character of a forest of nanotubes, this technique requires a reflective element to be deposited on the segment, this disrupting thermal and gaseous exchanges locally, and hence the height of the forest of nanotubes under the segment covered by the coating may be substantially different from the other segments of the forest.

The article Y. Hayashi et al., “Analysis of early stages of vertically aligned carbon nanotube growth by plasma-enhanced chemical vapor deposition”, Japanese Journal of Applied Physics, vol. 44, No. 4A, 2005 pp. 1549-1553 and the article D. B. Geoghegan et al., “In situ growth rate measurements and length control during chemical vapor deposition of vertically aligned multiwall carbon nanotubes”, Applied Physics Letters, Vol. 83, No. 9, 2003, pp 1851-1853 describe tracking the height of forests of nanotubes in growth by ellipsometry and reflectometry, respectively. The authors take advantage of these techniques to determine the height of a forest of nanotubes by quantifying the modification of the polarization and of the intensity of a light beam respectively, after reflection by a forest of nanotubes. Nevertheless, such techniques are penalized by the optical absorption of the forest of nanotubes. They are unsuitable for the measurement of the height of forests having a height larger than 10 μm. However, forests of nanotubes produced industrially have heights that may be larger than 100 μm.

There is therefore a need for a method that allows, reliably and reproducibly, the height of a forest of nanotubes to be measured under industrial growth conditions.

The invention meets this need and provides a method for measuring the height of a forest of carbon nanotubes, the method comprising the steps of:
a) providing a substrate having at least one growth area,
   the growth area containing at least one measurement zone comprising a growth zone and a zone sterile to the growth of the nanotubes, called the “virgin” zone, the growth zone being defined by a segment of the substrate containing a catalyst of the growth of the nanotubes, and
b) growing catalytically, within a chemical-vapour-deposition reactor, the forest of nanotubes in the growth zone,
   the method comprising, at least in step b):
irradiating the measurement zone by means of an incident light beam;
measuring, at various times, the intensity of the beam reflected by the measurement zone;
determining the height of the forest of nanotubes from the reflected-beam intensities measured at the various times (t).

A simple measurement of the height of the forest of carbon nanotubes may be taken by means of the method. In particular, the measurement of the height of the forest in the measurement zone is representative of the height of the forest able to grow in different zones and, in particular, zones far from the measurement zone. Moreover, the growth of the nanotubes in zones different from the measurement zone is not affected by the presence of the measurement zone. In particular, the method may be implemented without an element being deposited on the forest of nanotubes. Thus, the introduction of experimental artefacts into the determination of the height is limited.

Moreover, the method according to the invention requires few, or even no modifications to the CVD deposition reactor.

Furthermore, the measurement zone may be placed on a portion of the substrate that is intended to be sacrificed, for example cut, once the growth of the forests of nanotubes has finished. Thus, the method does not decrease the production yield of forests of nanotubes.

Moreover, the method allows the measurement of heights of forests of nanotubes produced industrially. In particular, as will become apparent below, depending on the shape and dimensions of the growth zone and the virgin zone, and the angle of incidence of the beam incident on the substrate, heights larger than 150 μm, or even larger than 500 μm, and better still larger than 1 mm, may be measured.

Preferably, the virgin zone is defined by another segment of the substrate that absorbs less and/or reflects more the incident light beam than the forest of nanotubes. Advantage is thus taken of the optically absorbing character of the nanotubes, which gradually occult during the growth of the forest, like a diaphragm, the intensity of the reflected beam.

Those skilled in the art are easily able to determine such properties. The absorption coefficient of a forest of carbon nanotubes, measured by optical spectroscopy, may be comprised between 0.95 and 0.9999 in the spectral wavelength range comprised between 200 nm and 20 μm, and for example higher than 0.97 at a wavelength equal to 635 nm.

For example, the substrate may comprise a virgin zone defined by alumina on silicon that has a reflection coefficient higher than 15% at a wavelength equal to 635 nm. The reflection coefficient may in particular be measured by reflectometry.

A “forest of nanotubes” designates an organized assembly of carbon nanotubes, in which assembly the nanotubes are substantially parallel to one another, and each oriented substantially perpendicularly to the growth area in which they are grown, and the height of which is close to the unitary length of the nanotubes.

By “catalytic growth” of the forest of nanotubes, what is meant is that the growth of the nanotubes of the forest is activated by means of the catalyst.

In step a), a substrate having a growth area for the catalytic growth of the carbon nanotubes is provided.

Those skilled in the art are able, as part of their routine activity, to choose such a catalyst.

The catalyst may in particular comprise an element chosen from iron, cobalt, nickel, palladium, and mixtures thereof.

Preferably, the substrate comprises a carrier and a coating partially covering the carrier. A “carrier” has a rigidity such that it does not break under the effect of its own weight.

Such a coating may be deposited on the carrier using various methods known to those skilled in the art. For example it may be deposited by e-beam evaporation.

Preferably, the coating contains the catalyst. The coating may be a multilayer coating. For example, it consists of a layer of aluminium of thickness possibly comprised between 1 nm and 100 nm and of a layer formed from the catalyst. It may also consist of a plurality of metal layers, for example of titanium and aluminium, and of a layer formed from the catalyst. The patent WO-A-2014/191915 describes an example of such a multilayer coating.

The carrier may consist of a metal sheet or block optionally covered with one or more oxides, for example alumina, or a carbon-containing material, for example graphene or amorphous carbon, or metals, for example aluminium, TaN or TiN. The carrier may be a multilayer carrier. For example, it consists of a silicon wafer in particular having a thickness larger than 0.3 mm, covered with an alumina layer of thickness possibly comprised between 1 nm and 100 nm.

The coating may be formed on the carrier, so as to define the growth zone and where appropriate the virgin zone, using a method chosen by a person skilled in the art. For example, the coating may be deposited through a mechanical mask, by means of resist masking, or obtained by ablation after the deposition of a coating or of the catalytic layer.

The coating has a first face facing the carrier and a second face opposite the first face. Preferably, the growth zone is defined by the second face.

Preferably, the virgin zone is at least partially defined by the segment of the face of the carrier called the “free segment”, which is complementary to the segment of the face of the carrier covered by the coating. The virgin zone is preferably defined by a segment of the carrier, for example the free segment, made of a material that is inert with respect to the growth of the nanotubes. Those skilled in the art are able to easily choose, as part of their routine activities, such an inert material.

The growth zone and the virgin zone are preferably contiguous. Preferably, the virgin zone is separated by two consecutive growth zones.

Preferably, the growth zone and the virgin zone define a measurement pattern, the measurement zone being defined by the regular, and preferably periodic, repetition, in at least one direction, of the measurement pattern. The measurement zone may be defined by the regular, and preferably periodic, repetition in two directions that may optionally be orthogonal.

The pattern may be repeated at least once, preferably at least 3 times, or even at least 10 times in at least one direction so that the measurement zone is of larger extent than the projected area of the light beam incident on the substrate.

For example, the measurement pattern may be repeated in two orthogonal directions such that the growth zones and virgin zone are arranged in the measurement zone in the manner of a chequerboard.

Preferably, the growth zone and the virgin zone each have a preferably rectilinear strip shape. The growth zone and the virgin zone may extend in parallel directions. They preferably extend in a common direction. In particular, they may share a common long edge and define the measurement pattern, which is preferably repeated periodically in a direction perpendicular to the common direction of extension.

Preferably, the strip-shaped growth zone has a width comprised between 30 μm and 500 μm, and for example equal to 200 μm, and/or the strip-shaped virgin zone has a width comprised between 30 and 10000 μm, and for example equal to 500 μm.

The measurement zone may have an outline of various shapes, for example a rectangular, circular, square or rhombus-shaped outline.

It may be placed in the central portion of the growth area or at the edge of the substrate.

Preferably, the area of the measurement zone is larger than the size of the light beam on the carrier.

Moreover, the substrate may comprise another growth zone, defined by another segment of the substrate comprising the catalyst, and placed at distance from the measurement zone. The other growth zone for example frames the measurement zone. The other growth zone is thus intended for the industrial production of a forest of nanotubes or of components incorporating forests of nanotubes.

The measurement zone may be placed on a portion of the substrate intended to be sacrificed at the end of the step of growing the forest of nanotubes. For example, at the end of the step of growing the nanotubes, the other growth zone may be covered with another forest of nanotubes, and the substrate may be cut along a scribe line including the measurement zone.

In step b), nanotubes are grown in the growth zone.

The growth of the forest of nanotubes is carried out in the chamber of a catalytic growth reactor by chemical vapour deposition.

The growth by CVD of the nanotubes may be carried out in a way that is conventional in the field in question. Those skilled in the art know how to define, as part of their routine activities, the parameters, in particular temperature, pressure and the flow rate of the precursor gases of the material from which the nanotubes are made, that allows the growth of the nanotubes in the growth area of a substrate placed in the chamber of the CVD reactor to be guaranteed.

For example, to make a forest of carbon nanotubes grow, a person skilled in the art may choose a carbon-containing precursor such as, for example, acetylene.

The substrate may be raised in the chamber to a temperature comprised between 350° C. and 900° C., and in particular comprised between 500° C. and 700° C.

The pressure of the chamber may be comprised between comprised between 0.1 mbar and 1000 mbar and in particular between 0.1 and 10 mbar.

Moreover, at least during the growth of the forest of nanotubes in step b), the height of the forest of nanotubes is determined.

The determination of the height of the forest of nanotubes requires, beforehand, the measurement zone to be irradiated by means of an incident light beam, then the intensity of the beam reflected by the measurement zone to be measured.

When a precursor of the nanotubes makes contact with the growth zone, a reaction catalysed by the catalyst takes place between the precursors of the nanotubes. The nanotubes then grow in a direction substantially perpendicular to the surface of the growth area of the substrate.

In contrast, in contact with the virgin zone, substantially no reaction takes place because of an absence of the catalyst. Substantially no nanotubes grow from the virgin zone. Thus, during the growth, the virgin zone remains substantially free of nanotubes. Moreover, the optical properties of the material of the portion of the substrate that defines the virgin zone preferably remain constant during the growth of the nanotubes.

The incident light beam may be monochromatic or polychromatic. In particular, the incident light beam may be a parallel laser beam, preferably having a wavelength comprised between 200 nm and 20 μm, or even between 350 nm and 700 nm, and for example equal to 635 nm. In particular, the incident light beam may have a diameter comprised between 1 μm and 1 cm.

As a variant, the incident light beam may be a visible and in particular polychromatic light beam having a spectrum of wavelengths comprised between 200 nm and 800 nm or even comprised between 380 nm and 780 nm.

The incident light beam may be emitted by a light source, for example a laser diode, connected to an electrical power source. The intensity of the incident light beam may thus easily determinable, if necessary.

The measurement zone may be irradiated during at least 50% of the duration of the growth step b) or throughout the growth of the forest of nanotubes.

The light source is preferably placed outside the chamber of the catalytic reactor. The one or more walls separating the chamber from the light source may comprise an aperture and/or a segment that is transparent to the incident light beam, for example a porthole made of quartz, for the transmission of the incident light beam from the source to the substrate. The light source is thus protected from the atmosphere and the effects of the temperature that may be found in the chamber during the deposition.

The maximum height of a forest of nanotubes able to be determined may be related to the value of the angle of incidence of the incident light beam. The angle of incidence is defined between the direction of the light beam and the surface of the growth area.

The angle of incidence of the incident light beam may be larger than 0°, preferably larger than 10° and/or smaller than 90°, for example smaller than 80°, and preferably comprised between 30° and 60°. Thus, during its growth, the forest of nanotubes defines a screen that prevents the incident radiation from reaching one portion of the virgin zone, which is called the “shaded portion”.

Moreover, in the variant in which the growth zone and the virgin zone each take the form of a strip, preferably the growth zone and the virgin zone are preferably perpendicular to the plane normal to the substrate containing the direction of propagation of the incident light beam. Such an arrangement of the measurement zone with respect to the incident light beam facilitates the determination of the height of the forest of nanotubes.

Preferably, the incident light beam irradiates at least 50% and preferably less than 90% of the area of the measurement zone.

The incident beam is reflected by the measurement zone.

The intensity of the reflected beam may be measured by means of a photodetector. The photodetector is preferably placed outside of the chamber, in order to protect it from the reactive gases and the temperature of the chamber. The one or more walls separating the chamber from the photodetector may comprise an aperture and/or another segment that is transparent to the reflected beam in order to transmit the beam reflected from the measurement zone to the photodetector.

The photodetector for example comprises a photodiode made of silicon. It may comprise a bandpass filter centred on the one or more wavelengths of the incident beam, which may be mounted on the photodiode, in order to decrease the influence of surrounding light. Moreover, a hot mirror may be mounted on the photodiode, in order to limit the influence of infrared radiation possibly emitted by the chamber and the objects that are contained therein, on the measurement of the intensity of the reflected radiation.

The measurement of the intensity of the reflected beam is preferably carried out continuously throughout the growth of the forest of nanotubes.

For example, the intensity of the light beam may be measured with a measurement frequency comprised between 0.1 Hz and 1 MHz.

The intensity of the reflected beam may decrease with an increase in the height of the forest of nanotubes. It may in particular decrease more rapidly in a first growth phase than in a second phase successive to the first phase.

In particular, the intensity of the reflected beam may decrease in a piecewise manner as a function of the height of the forest of nanotubes. Preferably, it decreases in a piecewise manner in first and second segments. The first segment contains attenuated oscillations, which result from optical interference that those skilled in the art will be able to recognize and exploit, for example by means of a conventional reflectometry technique. The second segment decreases linearly with the height of the forest of nanotubes.

In particular, the intensity of the reflected beam may decrease as a function of the height of the forest of nanotubes, until it reaches a minimum threshold intensity. Preferably, the maximum measurable height of the forest of nanotubes is determined at the first measurement time at which the intensity of the reflected beam reaches the minimum threshold intensity. The minimum threshold intensity may be zero or result from the effects of parasitic light reaching the photodetector.

The height of the forest of nanotubes is determined from intensities of the reflected beam, which intensities are measured at various times. In particular, the intensity of the reflected beam is measured at at least two different times during the growth.

Preferably, during at least some of the growth of the forest of nanotubes, the height of the forest of nanotubes increases, preferably in a continuously monotonic way, as a function of the decrease in the intensity of the reflected beam. Preferably, during at least some of the growth of the forest of nanotubes, the height of the forest of nanotubes increases, preferably in a continuously monotonic way and linearly as a function of the decrease in the intensity of the reflected beam.

The invention will possibly be better understood on reading the following detailed description and the appended drawings, in which:

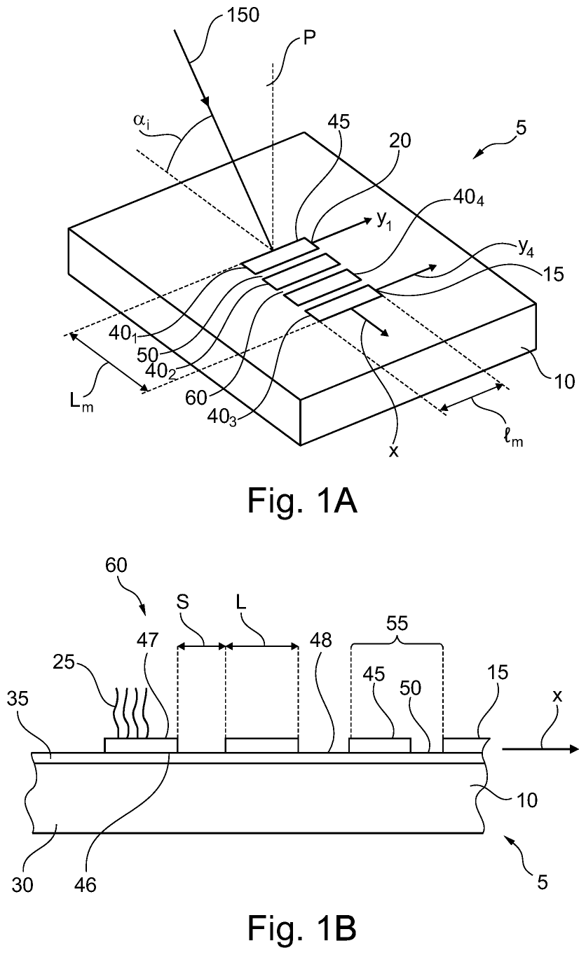

FIGS. 1a and 1b illustrate a substrate, seen in perspective and in cross section respectively, for implementing the method according to the invention,

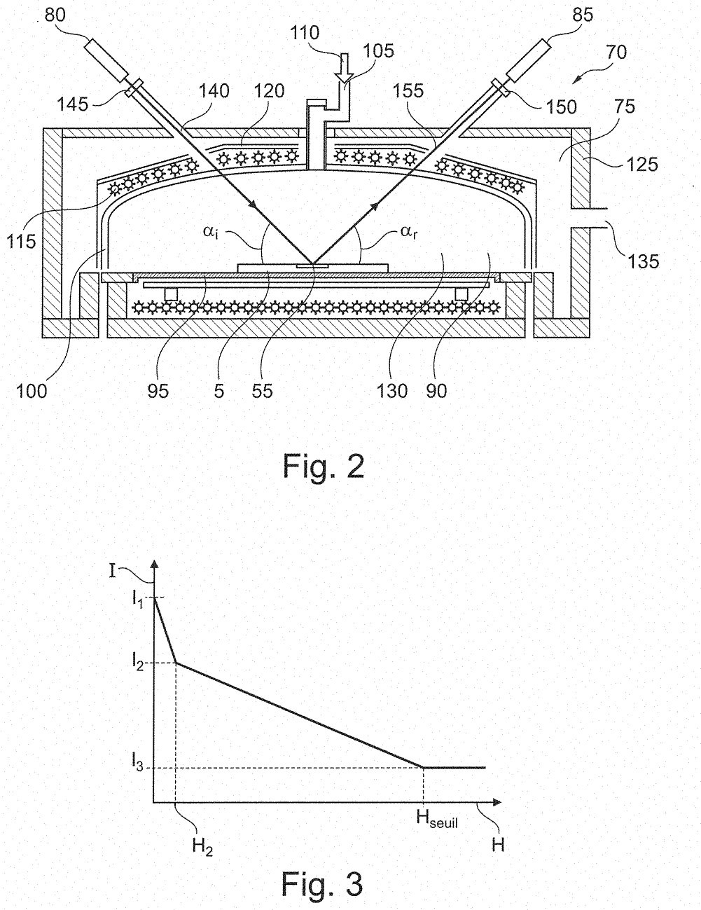

FIG. 2 illustrates a device for implementing the method according to the invention,

FIG. 3 is a graph schematically showing the variation in the intensity of the reflected beam as a function of the height of the forest of nanotubes,

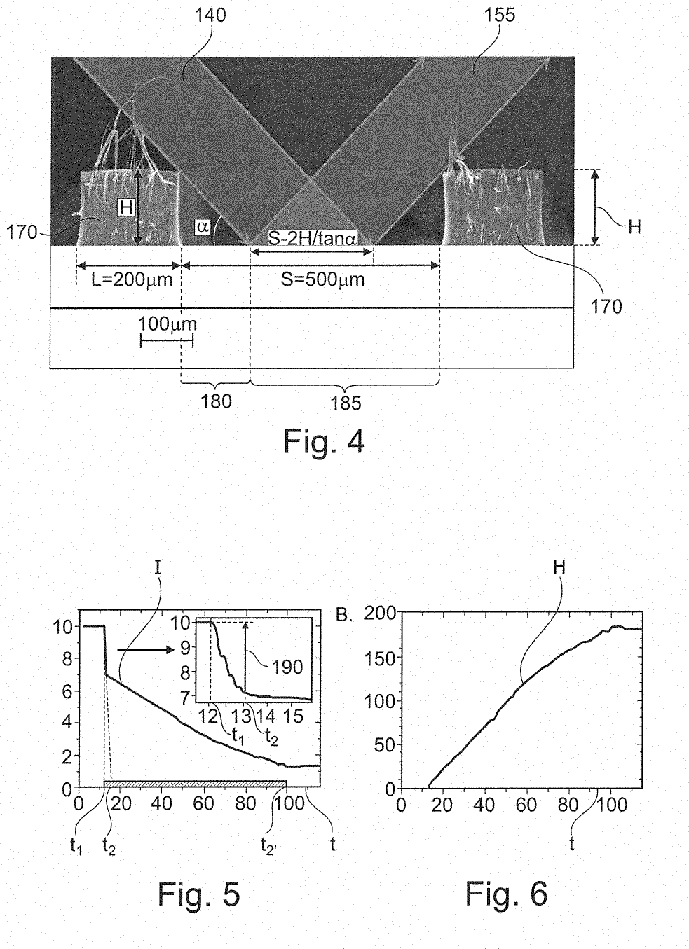

FIG. 4 is a scanning electron micrograph of a cross section of a substrate on which a forest of nanotubes has been grown according to an example of implementation of the method,

FIG. 5 is a graph showing the variation during one example of implementation of the method, the variation in the intensity of the reflected beam, and

FIG. 6 is a graph showing the variation in the height of the forest of nanotubes as a function of the duration of growth.

The elements shown in the drawings are not to scale.

FIGS. 1a-b illustrate an example of a substrate 5.

The substrate comprises a carrier 10 and a coating 15 covering the carrier. The substrate has a growth area 20 intended to receive the nanotubes 25 in growth.

The carrier comprises a silicon wafer 30, of length, width and thickness respectively equal to 30 mm, 30 mm and 0.5 mm. The wafer has a face completely covered with a thin layer 35 of alumina, deposited by atomic layer deposition (ALD), of a thickness of 10 nm. The coating makes contact with the alumina layer. It is deposited by e-beam evaporation.

The coating is a thin layer of iron, of a thickness of 1 nm. Iron is a catalyst of the growth of carbon nanotubes.

The coating takes the form of strips 40₁₋₄, each of a width L equal to 200 μm, placed parallel to one another and spaced apart periodically in a direction X perpendicular to the directions Y₁₋₄ of extension of the strips, the separation distance S between the strips of the coating being equal to 500 μm.

The coating comprises a first face 46 placed facing the carrier and a second face 47 opposite the first face, the second face defining a growth zone 45 for the forest of nanotubes. A segment (48) of the face of the carrier placed between two strips of the coating for its part defines a virgin zone 50 on the face of the substrate on which the coating is placed. The virgin zone is free of catalyst and thus sterile to the growth of the nanotubes.

The growth zone and the virgin zone thus define a measurement pattern 55 that is periodically repeated in the direction X, thus forming a measurement zone 60. The measurement zone has a rectangular outline of length Lₘ and width lₘ equal to 15 mm and 10 mm.

FIG. 2 illustrates an example of a device 70 for implementing the method according to the invention.

The device comprises a chemical-vapour-deposition reactor 75, a laser diode 80 and a photodetector 85.

The reactor comprises a chamber 90 within which the catalyst growth of the forest of nanotubes occurs. The CVD deposition reactor is for example a “wafer by wafer” reactor sold by the company Plassys.

The reactor comprises a heatable substrate holder 95 made of graphite housed in the chamber, and on which the substrate 5 illustrated in FIG. 1 is placed.

A bell jar 100 made of quartz surmounts the substrate holder and the substrate. It is equipped with an aperture 105 for the admission of precursor gases of the material of the nanotubes, which admission is illustrated by the arrow 110. In the example of FIG. 2, the precursor gas comprises acetylene, hydrogen and helium. The acetylene delivers the carbon required for the growth of a forest of carbon nanotubes.

Heatable elements 115 and thermal reflectors 120 are placed between the wall 125 of the chamber and the quartz bell jar for heating the reaction space 130 defined under the bell jar in which the catalysis reaction occurs.

The chamber furthermore comprises an outlet aperture 135 for the evacuation of the gaseous reaction products.

In the example of FIG. 2, the growth of the nanotubes is achieved by raising the substrate holder to a temperature of 600° C. The pressure in the chamber is 0.3 torr.

The laser diode is placed outside the chamber. It emits an incident light beam 140 in the form of a laser beam of a wavelength equal to 636 nm. It is oriented so that the laser beam is directed so as to irradiate the measurement zone 55. To this end, the wall of the chamber of the reactor furthermore comprises a porthole 145 made of quartz placed on the optical path of the incident laser beam.

The angle of incidence αᵢ of the laser on the measurement zone is 42°, said angle being defined between the direction of propagation of the laser and a normal \vec{n} to the substrate. As is shown in FIG. 1, the growth zones and the virgin zones, which all extend parallel to one another in strips in the directions Y₁₋₄, are placed perpendicular to the plane P containing the direction 150 of propagation of the incident laser beam.

The incident laser beam is reflected by the measurement zone, provided that the forest of nanotubes has not reached a height such that it prevents the incident laser beam from reaching the virgin zones.

The angle of reflection αᵣ of the reflected laser beam is equal to the angle of incidence.

The photodetector is placed outside of the chamber along the optical path of the reflected beam 155. The wall of the chamber furthermore comprises a window 160 made of quartz in order to isolate the photodetector from the chamber and to transmit the reflected beam.

The graph of FIG. 3 schematically shows the variation in the intensity I of the reflected beam as a function of the height H of the forest of nanotubes in the CVD reactor of FIG. 2.

Before the nanotubes are grown, the measurement zone reflects the incident laser beam, depending on the reflective properties of the thin alumina layer defining the virgin zone and the thin iron layer defining the growth zone. An intensity I₁ is measured.

From t=t₁, the nanotubes are grown. During the growth, no catalyst being present in the virgin zones, no nanotubes grow in the latter. In contrast, by interaction between the acetylene-containing precursor gas and the iron, carbon nanotubes grow in the growth zones. In the illustrated example, the growth zones are reflective before the carbon nanotubes grow. The forest of nanotubes no longer reflects the incident laser beam once it reaches, at the time t₂, a height H₂, which in the illustrated example is about 4 μm, as may be verified subsequently by means of a measurement of a micrograph for example taken by scanning electron microscopy, or of a reflectivity measurement performed on a segment of substrate exempt of “virgin” zone. The intensity therefore rapidly decreases as a function of the height H between the start of the growth when the height is zero and the height H₂. Provided that the height is smaller than H₂, the forest of carbon nanotubes is semi-transparent and it is possible to observe optical interferences as may be seen in the curve illustrated in FIG. 5.

When the height H increases, as is illustrated in FIG. 4, the forest 170 of nanotubes absorbs some of the laser beam and, in this way, forms a shadow 180 on the virgin zone. The portion 185 of the virgin zone irradiated by the incident laser beam that is reflected thus decreases linearly with the increase in height. It is then equal to S−2H/tan(α). The intensity of the reflected beam thus also decreases linearly until a minimum threshold intensity I₃, for which the forests of nanotubes having grown on the growth zones form screens shadowing all the virgin zones, is reached. Substantially no beam is then reflected by the measurement zone. The minimum threshold intensity I₃ therefore corresponds to the maximum height of the forest of nanotubes able to be measured. It may be nonzero and correspond to the intensity of the parasitic radiation measured by the photodetector.

In the illustrated example, the intensity I₂ respects the following equation (1):

$$\frac{{I}_{2} - {I}_{3}}{{I}_{1} - {I}_{3}} = \frac{S}{S + L} \qquad ( 1 )$$

When the intensity of the reflected beam is comprised between I₂ and I₃, the height H of the forest may be determined, approximately, by solving equation (2)

$$\frac{{I}_{2} - {I}_{3}}{{I}_{1} - {I}_{3}} = \frac{S - 2 H \text{/} tan ( α )}{S + L} \qquad ( 2 )$$

Equation (2) provides a determination of the height H with a measurement precision of about H₂/2.

For example, in the illustrated example, the intensities I₁ and I₃ expressed as output voltage measured across the photodiode are equal to 10 V and 0 V.

The variation in the intensity I, expressed in volts, of the reflected beam as a function of the duration of growth t of the forest of nanotubes is illustrated in FIG. 5. The growth of the nanotubes is carried out between t₁ and t₂′. As explained above, the intensity rapidly decreases between the times t₁ and t₂, at which time the forest reaches the height H₂. The attenuation 190 of the intensity between the times t₁ and t₂ respects equation (1). Subsequently, the intensity of the reflected beam decreases more slowly during the growth of the forest of nanotubes up to the time t_{2′}.

By means of equation 2, the height H of the forest of carbon nanotubes may be determined with a precision of H₂/2 as a function of the duration of growth t, as illustrated in FIG. 6. A height of forest reaching 185±2 μm is measured in this example. The height H₂ is 4 μm for the example of implementation of the method.

The method according to the invention is therefore particularly well suited to measuring the height of forests of nanotubes obtained within industrial reactors.

The invention is not limited to the examples of implementation described here for illustrative purposes.

In particular, other measurement patterns of more complex shape may be envisioned. Those skilled in the art will then easily be able to adapt equations (1) and (2) accordingly.

For example, to facilitate the positioning of the measurement zone with respect to the incident beam, the measurement zone may be formed from a plurality of virgin zones placed so as to form a hexagonal array, the virgin zones having a circular outline and being encircled by a surrounding growth zone.

1: A method for measuring a height of a forest of carbon nanotubes, the method comprising:
a) providing a substrate having a growth area,
the growth area comprising a measurement zone comprising a growth zone and a zone sterile to growth of the carbon nanotubes, called a “virgin” zone, and the growth zone being defined by a segment of the substrate comprising a catalyst of the growth of the carbon nanotubes, and
b) growing catalytically, in a chemical-vapour-deposition reactor, the forest of carbon nanotubes in the growth zone,
wherein the growing comprises
irradiating the measurement zone by means of an incident light beam;
measuring, at various times, an intensity of the incident light beam reflected by the measurement zone; and
determining the height of the forest of carbon nanotubes from reflected-beam intensities measured at the various times.

2: The method according to claim 1, wherein the virgin zone is defined by another segment of the substrate that absorbs less and/or reflects more the incident light beam than the forest of carbon nanotubes.

3: The method according to claim 1, wherein the substrate comprises a carrier and a coating partially covering the carrier, and
the coating comprises the catalyst.

4: The method according to claim 3, wherein the coating comprises a first face placed facing the carrier and a second face opposite the first face, and
the growth zone is defined by the second face.

5: The method according to claim 1, wherein the substrate comprises a carrier, and
the virgin zone is defined by a segment of the carrier made of a material that is inert with respect to the growth of the carbon nanotubes.

6: The method according to claim 1, wherein the substrate comprises a carrier and a coating partially covering the carrier, and
the virgin zone is at least partially defined by a segment of a face of the carrier that is complementary to a segment of the face of the carrier covered by the coating.

7: The method according to claim 1, wherein the growth zone and the virgin zone define a measurement pattern, the measurement zone being defined by a regular repetition, in at least one direction of the measurement pattern.

8: The method according to claim 1, wherein the growth zone and the virgin zone each has a rectilinear strip shape.

9: The method according to claim 1, wherein the growth zone has a width of between 30 μm and 500 μm, and/or the virgin zone has a width of between 30 μm and 10000 μm.

10: The method according to claim 1, wherein the growth zone and the virgin zone are perpendicular to a plane containing a direction of propagation of the incident light beam.

11: The method according to claim 1, wherein the incident light beam is a parallel laser beam.

12: The method according to claim 1, wherein an angle of incidence (αᵢ) of the incident light beam is larger than 0°.

13: The method according to claim 1, wherein, during at least some of the growth of the forest of carbon nanotubes, the height of the forest of carbon nanotubes increases as a function of decrease in an intensity of reflected beam.

14: The method according to claim 15, wherein, during at least some of the growth of the forest of carbon nanotubes, the height of the forest of carbon nanotubes increases in a continuously monotonic way linearly as a function of the decrease in the intensity of the reflected beam.

15: The method according to claim 13, wherein, during at least some of the growth of the forest of carbon nanotubes, the height of the forest of carbon nanotubes increases, in a continuously monotonic way, as a function of the decrease in the intensity of the reflected beam.
